(19) United States
(12) Patent Application Publication
(10) Pub. No.: US 2017/0373099 A1
(43) Pub. Date: Dec. 28, 2017

(54) ARRAY SUBSTRATE, MANUFACTURING METHOD THEREOF AND DISPLAY DEVICE

(71) Applicants: BOE Technology Group Co., Ltd., Beijing (CN); Beijing BOE Optoelectronics Technology Co., Ltd., Beijing (CN)

(72) Inventors: Zijin LIN, Beijing (CN); Haisheng ZHAO, Beijing (CN); Zhilong PENG, Beijing (CN); Dongjiang SUN, Beijing (CN)

(21) Appl. No.: 15/537,209

(22) PCT Filed: Aug. 4, 2016
(86) PCT No.: PCT/CN2016/093240

§ 371 Date: Jun. 16, 2017

(30) Foreign Application Priority Data
Jan. 4, 2016 (CN) 201610006819.8

(51) Int. Cl. H01L 27/12; G02F 1/1343; G02F 1/1362

(52) U.S. Cl. CPC H01L 27/1262; H01L 27/124; G02F 1/136286; G02F 1/1343; G02F 1/136277; G02F 1/136227; G02F 2201/123

(57) ABSTRACT

Disclosed are an array substrate, a manufacturing method thereof, and a display device. The array substrate includes a gate insulating layer, an active layer, source-drain electrodes, a first conductive layer and an isolation insulating layer), the source-drain electrodes are in contact with the active layer, the gate insulating layer is located on a surface of the active layer, the isolation insulating layer) is located on another surface of the active layer, and the isolation insulating layer at least includes a first hollow structure in a contacting region of the active layer and the source-drain electrodes; the isolation insulating layer is configured to isolate residue of the active layer located outside a region where the first hollow structure is located from contacting the first conductive layer.

### TECHNICAL FIELD

Embodiments of the present disclosure relate to an array substrate, a manufacturing method of the array substrate, and a display device.

### BACKGROUND

With the continuous development of display technology, TFT-LCD, short for thin film transistor liquid crystal display, becomes more and more popular in the market. Generally, the basic structure of the TFT-LCD comprises an array substrate, an opposed substrate and a liquid crystal layer sandwiched between the array substrate and the opposed substrate.

An array substrate is provided with a plurality of sub-pixel units arranged in a matrix, each of the sub-pixel units is provided with a thin film transistor (TFT). A thin film transistor generally comprises a gate electrode, a gate insulating layer, an active layer, source-drain electrodes and so on.

### SUMMARY

Embodiments of the present disclosure provide an array substrate, a manufacturing method thereof, and a display device, so as to solve the problem of electrical defects of a TFT caused by the residue of an active layer lapping with a conductive layer in the existing art.

At least one embodiment of the present disclosure provides an array substrate, the array substrate comprises a gate insulating layer; an active layer; source-drain electrodes, being in contact with the active layer; a first conductive layer; and an isolation insulating layer, the gate insulating layer is located on a surface of the active layer, the isolation insulating layer is located on another surface of the active layer, and the isolation insulating layer at least comprises a first hollow structure in a contacting region of the active layer with the source-drain electrodes; the isolation insulating layer is configured to isolate residue of the active layer outside a region where the first hollow structure is located from contacting the first conductive layer.

At least one embodiment of the present disclosure provides a manufacturing method of an array substrate, the manufacturing method comprises: forming a gate insulating layer; forming an active layer with a first pattern; forming source-drain electrodes with a second pattern and a first conductive layer with a third pattern, the source-drain electrodes being in contact with the active layer; and forming an isolating insulating layer with a fourth pattern, the gate insulating layer is located on a surface of the active layer, the isolation insulating layer is located on another surface of the active layer, and the isolating insulating layer at least comprises a first hollow structure in a contacting region of the active layer with the source-drain electrodes; the isolation insulating layer is configured to isolate residue of the active layer from contacting any conductive layer.

At least one embodiment of the present disclosure further provides a display device, which comprises the array substrate according to any one of the above mentioned array substrates.

In an embodiment of the present disclosure, a surface of the active layer is provided with a gate insulating layer, another surface is provided with an isolation insulating layer, the isolation insulating layer can effectively isolate the residue of the active layer from separately contacting the data line and the pixel electrode, so as to avoid electrical defects of the TFT. Besides, the isolation insulating layer reduces the height difference of the surface of the film layers of the whole array substrate after forming the active layer, improves the flatness of the surface of the film layers of the whole array substrate, and reduces the phenomenon that film layers break due to a relatively large height difference or slope angle of the surface of the film layers.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure, for one skilled person in the art, other drawings can be obtained according to these drawings without inventive work.

FIG. 1 is a schematic diagram showing that residue of an active layer is lapped with a data line and a pixel electrode in an existing art;

FIG. 2 (a) is a first structural schematic diagram of an array substrate related by an embodiment of the present disclosure, wherein the array substrate is an array substrate with a bottom gate structure;

FIG. 2 (b) is a second structural schematic diagram of an array substrate related by an embodiment of the present disclosure, wherein the array substrate is an array substrate with a bottom gate structure;

FIG. 2 (c) is a third structural schematic diagram of an array substrate related by an embodiment of the present disclosure, wherein the array substrate is an array substrate with a bottom gate structure;

FIG. 2 (d) is a fourth structural schematic diagram of an array substrate related by an embodiment of the present disclosure, wherein the array substrate is an array substrate with a bottom gate structure;

FIG. 3 is a structural schematic diagram of an array substrate related by an embodiment of the present disclosure, wherein the array substrate is an array substrate with a top gate structure;

FIG. 4 is a flow diagram of a manufacturing method of an array substrate with a bottom gate structure provided by an embodiment of the present disclosure; and

FIG. 5 is a flow diagram of a manufacturing method of an array substrate with a top gate structure provided by an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, one person skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” and so on which are used in the description and the claims of the present application for invention, are not intended to indicate any sequence, amount or importance, but distinguish various components. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

Generally, in a manufacturing process of an active layer (or a semiconductive layer), firstly depositing SiNx, a-Si, and N+a-Si, and then performing a patterning process to the deposited mixed film layers, so as to form a patterned active layer.

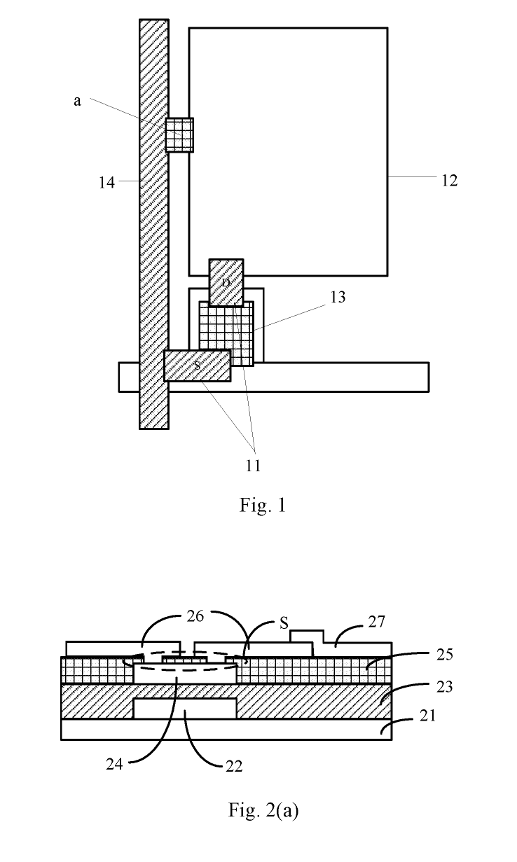

However, in the research, the inventor(s) of the present application notices that: during the practical preparing process, it is unavoidable that the above mentioned mixed film layers are attached with foreign matters such as dusts and scraps due to the preparing environment and apparatus or other abnormal reasons. These foreign matters can be attached during the depositing process, the coating process or the etching process. Upon a dry etching process being performed, the gas used for the dry etching process cannot contact and react with the film layers because foreign matters are located at some positions of the mixed film layers, as a result, residue of the film layers appears. For example, upon a dry etching process being applied to pattern an active layer, in a region where the foreign matters exist, the active layer cannot be etched and residue of the active layer appears. Furthermore, as illustrated in FIG. 1, upon source-drain electrodes 11 and a pixel electrode 12 being formed in the following, if the residue a of the active layer 13 is large enough, the residue a may cause an electrical connection between the data line 14 and the pixel electrode 12, as illustrated in FIG. 1, it is easy for the electrical connection to result in electrical defects of a TFT.

At least one embodiment of the present disclosure provides an array substrate, a manufacturing method thereof, and a display device. The array substrate comprises: a gate insulating layer, an active layer, source-drain electrodes being in contact with the active layer, and a first conductive layer; besides, the array substrate further comprises: an isolation insulating layer. The gate insulating layer is located on a surface of the active layer, the isolation insulating layer is located on another surface of the active layer, and the isolation insulating layer at least comprises a first hollow structure in a contacting region of the active layer with the source-drain electrodes; the isolation insulating layer is configured to isolate residue of the active layer from contacting any first conductive layer. In the structure of the array substrate, one surface of the active layer is provided with the gate insulating layer, besides, another surface of the active layer (except the contacting region of the active layer with source-drain electrodes) is further provided with the isolation insulating layer. In this way, the active layer is effectively isolated with other adjacent first conductive layer, and it can be avoided that the residue of the active layer laps with any first conductive layer, especially, the situation that the residue of the active layer laps with a pixel electrode and a data line can be effectively avoided. Thus, the problem of electrical defects of a TFT caused by lapping can be solved. Meanwhile, due to the addition of the isolation insulating layer, and the thickness of the film layers can be properly adjusted, such that the height difference of the surface of the film layers of the whole array substrate after forming the active layer is reduced, and the flatness of the surface of the film layers is improved. Therefore, in a case where the slope angle of the surface of the film layers is relatively small, the subsequent film layers can be deposited well, and the phenomenon that film layers break due to a relatively large height difference and slope angle of the surface of the film layers can be reduced.

The first conductive layer related in the embodiment of the present disclosure comprises any one selected from a group consisting of a data line, a pixel electrode, a gate line, and a common electrode.

In the embodiment of the present disclosure, the isolation insulating layer comprises a second hollow structure in a region where a pixel electrode is located. In this way, in the premise of guaranteeing that the isolation insulating layer can effectively isolate the residue of the active layer lapping with and contacting other first conductive layer, the light transmittance of the entire array substrate can be improved by forming the second hollow structure in the region where the pixel electrode is located.

Hereafter, the array substrate, the manufacturing method thereof, and the display device according to the present disclosure will be described in detail through specific embodiments, certainly, the present disclosure comprises but is not limited to the embodiments described below.

### First Embodiment

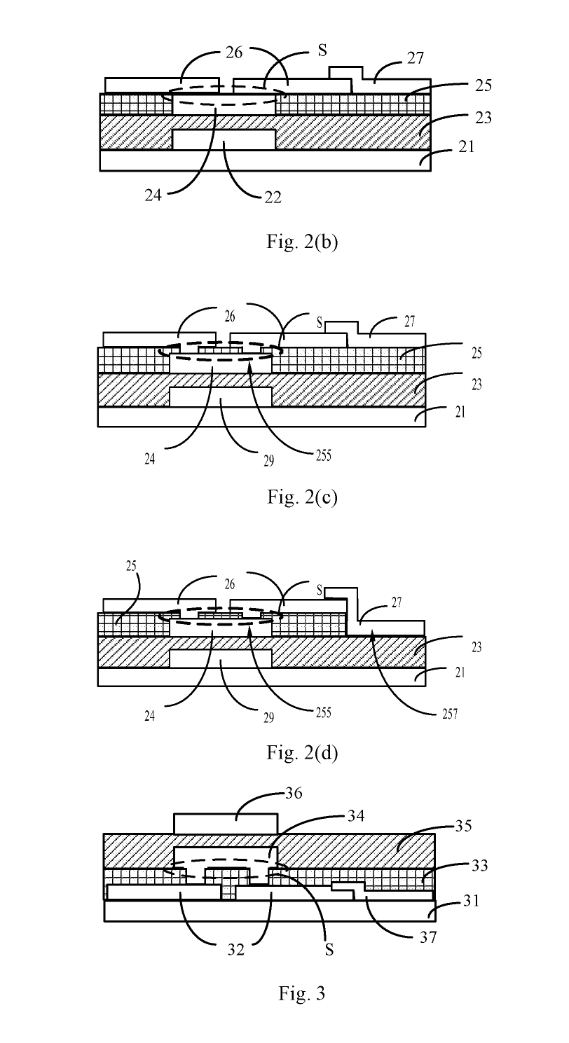

The present embodiment provides an array substrate. FIG. 2 (a) is a structural schematic diagram of an array substrate provided by an embodiment of the present disclosure, wherein the array substrate is an array substrate with a bottom gate structure. A case where the first conductive layer is a pixel electrode is described as an example in the present embodiment. As illustrated in FIG. 2), in the array substrate, a gate line 22 is located on a base substrate 21, a gate insulating layer 23 is located on the gate line 22 and covers the array substrate, an active layer 24 is located on the gate insulating layer 23, an isolation insulating layer 25 is located on the active layer 24, the isolation insulating layer 25 exposes the active layer 24 in a contacting region S of the active layer 24 (assuming that the active layer 24 has residue a) and source-drain electrodes 26 through a first hollow structure, the source-drain electrodes 26 are located on the isolation insulating layer 25, and contact the exposed portion of the active layer 24. Besides, a pixel electrode 27 laps with and contacts the source-drain electrodes 26, and the isolation insulating layer 25 isolates the pixel electrode 27 from lapping with the residue a. In this structure, the first hollow structure of the isolation insulating layer 25 in the contacting region S of the active layer 24 and the source-drain electrodes 26 may be via holes, the source-drain electrodes 26 respectively contact the active layer 24 below through the via holes, so as to guarantee the characteristics of a thin film transistor. It is to be noted that, the above mentioned array substrate with the bottom gate structure represents that the thin film transistors on the array substrate adopt the bottom gate structure. Similarly, an array substrate with a top gate structure represents that the thin film transistors on the array substrate adopt the top gate structure. Besides, the above mentioned pixel electrode 27 is the first conductive layer.

For example, in an array substrate provided by an example of the present embodiment, FIG. 2 (b) is another structural schematic diagram of an array substrate related by the present disclosure, wherein the array substrate is an array substrate with a bottom gate structure, as illustrated in FIG. 2 (b), the structure of the array substrate is similar to that of the array substrate in FIG. 2 (a), and the distinction lies in that: the isolation insulating layer 25 is flush with the active layer 24, the isolation insulating layer 25 exposes the active layer 24 through the first hollow structure in the contacting region S of the active layer 24 and the source-drain electrodes 26. In this way, the source-drain electrodes 26 respectively contact the active layer 24, so as to guarantee the characteristics of a thin film transistor.

For example, in an array substrate provided by an example of the present embodiment, as illustrated in FIG. 2 (c), the array substrate further comprises a gate electrode 29, the gate electrode 29 is electrically connected with the gate line 22. The gate electrode 29 and the active layer 24 are correspondingly disposed, that is to say, an orthographic projection of the gate electrode 29 on the base substrate 21 at least partially overlaps with that of the active layer 24 on the base substrate 21, thus, the electrical properties of the active layer 24 can be changed by applying an electrical signal to the gate electrode 29, so as to realize on-off of a thin film transistor. The gate electrode 29 and the gate line 22 can be formed by using the same material through one patterning process.

For example, in an array substrate provided by an example of the present embodiment, as illustrated in FIG. 2 (c), the first hollow structure 255 may be via holes corresponding to the source-drain electrodes. Certainly, the embodiments of the present disclosure comprise but are not limited thereto, and the first hollow structure can be a structure that the isolation insulating layer is totally removed in the contacting region.

For example, in an array substrate provided by an example of the present embodiment, FIG. 3 is a structural schematic diagram of an array substrate related by the present disclosure, wherein the array substrate is an array substrate with a top gate structure. As illustrated in FIG. 3, in the array substrate, source-drain electrodes 32 are located on the base substrate 31, an isolation insulating layer 33 is located on the source-drain electrodes 32, and the isolation insulating layer 33 exposes the source-drain electrodes 32 in the contacting region S of an active layer 34 and the source-drain electrodes 32 through the first hollow structure; the active layer 34 is located on the isolation insulating layer 33, and contacts the exposed portion of the source-drain electrodes 32; a gate insulating layer 35 is located on the active layer 34 and covers the array substrate; a gate line 36 is located on the gate insulating layer 35. Besides, in the same film layer of the source-drain electrodes 32, a pixel electrode 37 is provided, and laps with and contacts the source-drain electrodes 32.

In the structural film layers of above mentioned three kinds of array substrates provided by the present embodiment, during the process of forming the active layer, especially, during a depositing process or an etching process, if the surface of the film layers (for example, a surface of the active layer) is attached with foreign matters, such as dusts and scraps, residue of the active layer remains in a region where the active layer should be etched and removed. However, the array substrate provided by the present embodiment is provided with the isolation insulating layer on the active layer (a bottom gate structure) or the source-drain electrodes (a top gate structure), and the isolation insulating layer comprises the first hollow structure in the contacting region of the active layer with the source-drain electrodes to guarantee the effectiveness of a TFT. Thus, the existence of the isolation insulating layer effectively isolates the active layer from contacting the other adjacent film layers (the source-drain electrodes can contact the active layer through the first hollow structure), so as to prevent the residue of the active layer from lapping with and contacting any first conductive layer, particularly effectively prevent the residue of the active layer from lapping with and contacting the pixel electrode (the pixel electrode is located on or under the source-drain electrodes, and the pixel electrode laps with and contacts the drain electrode, and the existence of the isolation insulating layer isolates the residue from lapping with and contacting the pixel electrode) and the data line. Furthermore, the problem of electrical defects of the TFT caused by the lapping structure is solved. Meanwhile, due to the addition of the isolation insulating layer, the thickness of the film layers can be properly adjusted, in this way, after forming the active layer, the height difference of the surface of the film layers of the entire array substrate is reduced, and the flatness of the surface of the film layers is improved. Therefore, in a case where the slope angle of the surface of the film layers is relatively small, the subsequent film layers can be better deposited, and the phenomenon that the film layers break due to a relatively large height difference or a relatively large slope angle can be reduced. For example, upon the array substrate provided by the present embodiment being an array substrate with a bottom gate structure, as illustrated in FIG. 2 (a)-FIG. 2 (c), the isolation insulating layer 25 is disposed on the active layer 24 and covers the entire gate insulating layer 23, besides, the isolation insulating layer 25 is provided with a first hollow structure or entirely removed on the active layer 24, thus, the height difference between a region where the active layer 24 is located and the other region is reduced. Upon the source-drain electrodes and the pixel electrode being formed in the subsequent steps, the risk that the film layers break due to a relatively large height difference or a relative large slope angle of the surface of the film layers can be reduced.

For example, in an array substrate provided by an example of the present embodiment, as illustrated in FIGS. 2 (a)-2 (c), thickness of the isolation insulating layer 25 is larger than or equal to that of the active layer 24. Thus, the isolation insulating layer can better reduce the height difference of the array substrate between the region where the active layer is located and the other region.

For example, in an array substrate provided by an example of the present embodiment, as illustrated in FIG. 2 (a)-FIG. 2 (c), the pixel electrode 27 and the source-drain electrodes 26 are disposed in the same layer, the passivation layer can be omitted, so as to reduce the thickness of the array substrate and improve the entire light transmittance of the array substrate.

For example, in an array substrate provided by an example of the present embodiment, as illustrated in FIG. 2 (d), the isolation insulating layer 25 may comprise a second hollow structure 257 in a region where the pixel electrode 27 is located, so as to improve the entire light transmittance of the array substrate.

For example, in an array substrate provided by an example of the present embodiment, resin can be selected as a material of the isolation insulating layer. Due to the relatively good insulativity, resin material can well isolate the residue of the active layer from lapping with the other first conductive layers. It is to be noted that, in order to improve the entire light transmittance of the array substrate, resin with relatively small light transmittance can be selected as the material of the isolation insulating layer.

For example, in an array substrate provided by an example of the present embodiment, photosensitive resin can be selected as the material of the isolation insulating layer. Because the photosensitive resin can be well decomposed in lighting conditions. Thus, upon the isolation insulating layer being patterned, the photosensitive resin can be decomposed by only performing exposing and developing processes to the corresponding region, so as to obtain a required pattern. In this way, the technological processes can be simplified, and the problem of complex technological processes caused by using other non-photosensitive material which needs to use photoresist can be avoided.

Based on the same invention concept of the above mentioned array substrate, the present disclosure further provides a manufacturing method of an array substrate. The method comprises the following steps: forming a gate insulating layer; forming an active layer with a first pattern; forming source-drain electrodes with a second pattern and a first conductive layer with a third pattern, the source-drain electrodes are in contact with the active layer; besides, the method further comprises: forming an isolation insulating layer with a fourth pattern, wherein the gate insulating layer is located on a surface of the active layer, the isolation insulating layer is located on another surface of the active layer, and the isolation insulating layer at least comprises a first hollow structure in a contacting region of the active layer with the source-drain electrodes; the isolation insulating layer is configured to isolate residue of the active layer from lapping with any first conductive layer.

It is to be noted that, the above mentioned steps do not reflect obvious manufacturing sequence. Besides, the patterning process mentioned in the following embodiments at least comprises a step of coating or dropping photoresist, a step of exposing, a step of developing, a step of photolithography and etching and the like.

Hereafter, the manufacturing method of an array substrate provided by the present disclosure will be described in detail according to the types of the array substrates.

### Second Embodiment

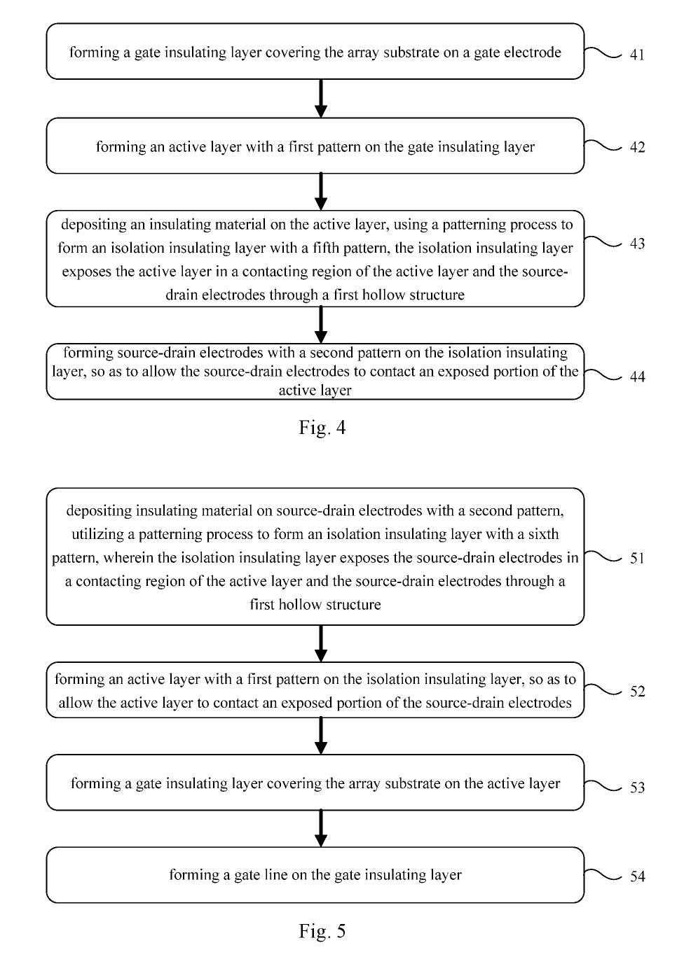

The present embodiment provides a manufacturing method of an array substrate, the array substrate is an array substrate with a bottom gate structure. As illustrated in FIG. 4, the manufacturing method of an array substrate comprises the following steps 41-44:

Step 41: forming a gate insulating layer covering the array substrate on a gate electrode.

For example, the step 41 can adopt a physical deposition method or a chemical deposition method to deposit one or more insulating layers to form the gate insulating layer, and the gate insulating layer covers the gate electrode and the array substrate. The method of forming the gate insulating layer is not limited thereto, and the material of the gate insulating layer is not limited thereto. Besides, the gate insulating layer may be a signal layer insulating layer or a composite insulating layer comprising a plurality of insulating layers, the embodiments of the present disclosure are not limited thereto.

It is to be noted that, before the step 41, the method may further comprise a step of forming the gate electrode on a base substrate, the forming process can refer to a normal forming process, and the repeated portions are omitted herein.

Step 42: forming an active layer with a first pattern on the gate insulating layer.

For example, using a chemical vapor deposition method, a thermal evaporation method, or other methods to deposit a semiconductor layer on the array substrate with the gate electrode and the gate insulating layer formed thereon, in the semiconductor layer, SiNx, a-Si, and N+a-Si are sequentially deposited; then, forming a photoresist layer with preset thickness on the array substrate with the semiconductor layer formed thereon, at this time, the photoresist layer covers the entire semiconductor layer used for forming the active layer; performing exposure and development to the photoresist layer through a first mask plate, remaining the photoresist located right on the active layer to be formed, and removing the photoresist located at the other positions; after that, performing an etching process to the exposed semiconductor layer; and finally stripping the remaining photoresist to expose the remaining semiconductor as the active layer with the first pattern. The photoresist related in the present disclosure may adopt positive photoresist or negative photoresist.

Step 43: depositing an insulating material on the active layer, using a patterning process to form an isolation insulating layer with a fifth pattern, the isolation insulating layer exposes the active layer in a contacting region of the active layer with the source-drain electrodes through a first hollow structure.

Based on the active layer formed in the above mentioned step 42, in consideration of residue formed during the process of forming the active layer, in order to avoid the problem of electrical defects of a TFT caused by the residue lapping with and contacting the other first conductive layer, the step 43 utilizes a physical vapor deposition or a chemical vapor deposition to form one or more insulating layers on the active layer with the first pattern, and utilizes a patterning process to form the isolation insulating layer with the fifth pattern, the isolation insulating layer exposes the active layer in the contacting region of the active layer with the source-drain electrodes through the first hollow structure.

For example, upon a pattering process being utilized to form the isolation insulating layer with the fifth pattern, one of the following modes can be selected according to the type of the insulating material:

### First Mode

In a case where a material of the insulating layer is non-photosensitive resin, with regard to an array substrate with an insulating layer deposited thereon, forming phototresist (for example, positive photoresist) with preset thickness on the insulating layer, utilizing a mask with a fifth pattern to expose the photoresist in a region corresponding to the active layer, after that, performing development to the array substrate being subjected to an exposure treatment, removing the photoresist being subjected to exposure, performing an etching treatment to the insulating layer in the region where the photoresist is removed, and stripping the photoresist in a region corresponding to the active layer, so as to expose the active layer and form an isolation insulating layer with the fifth pattern.

Second Mode

In a case where a material of the insulating layer is photosensitive resin, with regard to an array substrate with an insulating layer deposited thereon, it is not needed to form a photoresist layer with preset thickness on the insulating layer. A mask with a fifth pattern can be directly employed to expose the photosensitive resin in a region corresponding to the active layer, after that, performing a development treatment to the array substrate being subjected to an exposure treatment, to dissolve away the photosensitive resin in the exposed region and finally expose the active layer, so as to form an isolation insulating layer with the fifth pattern.

To sum up, the two modes can form the isolation insulating layer with a required pattern. However, the technical solution using the photosensitive resin in the second mode is more convenient, it is not needed to coat photoresist and perform a stripping treatment to the photoresist. In this way, the preparing processes are simplified.

Step 44: forming source-drain electrodes with a second pattern on the isolation insulating layer, so as to allow the source-drain electrodes to contact an exposed portion of the active layer.

For example, forming source-drain electrodes connected with the active layer through via holes or the exposed surface of the active layer on the isolation insulating layer with the fifth pattern, wherein the source electrode and the drain electrode are not in contact with each other.

### Third Embodiment

The present embodiment provides a manufacturing method of an array substrate. The array substrate is an array substrate with a top gate structure. As illustrated in FIG. 5, the manufacturing method of an array substrate comprises the following steps 51-54:

Step 51: depositing an insulating material on source-drain electrodes with a second pattern, utilizing a patterning process to form an isolation insulating layer with a sixth pattern, wherein the isolation insulating layer exposes the source-drain electrodes in a contacting region of the active layer with the source-drain electrodes through a first hollow structure.

For example, utilizing the above mentioned depositing process to deposit the insulating material on the source-drain electrodes with the second pattern, and utilizing a patterning process similar to that in step 43 to form the isolation insulating layer with the sixth pattern, the isolation insulating layer exposes the source-drain electrodes in the contacting region of the active layer with the source-drain electrodes through the first hollow structure. For example, combined with a structure illustrated in FIG. 3, utilizing a mask with the sixth pattern to form the first hollow structure comprising two via holes in a region corresponding to the active layer in the insulating layer, so as to respectively expose the source electrode and the drain electrode, i.e. the source-drain electrodes, through the two via holes.

It is to be noted that, before the step 51, the method further comprises a step of forming source-drain electrodes with the second pattern on a base substrate, the formation of the source-drain electrodes can refer to a normal forming method, and the material of source-drain electrodes can refer to a normal design, the repeated portions are omitted herein.

Step 52: forming an active layer with a first pattern on the isolation insulating layer, so as to allow the active layer to contact an exposed portion of the source-drain electrodes.

Based on the isolation insulating layer formed in step 51, wherein the isolation insulating layer comprises two via holes, depositing a semiconductor layer, the semiconductor layer respectively contacts the source-drain electrodes at the positions of the two via holes, then, performing a patterning process to the semiconductor lay to form the active layer with the first pattern. The step is similar to the step 42. As seen, even if residue of the active layer appears in the step, due to the existence of the isolation insulating layer, the residue does not lap with or contact a pixel electrode or other first conductive layer. As a result, good electrical properties of a TFT can be well guaranteed.

Step 53: forming a gate insulating layer covering the array substrate on the active layer.

Step 54: forming a gate line on the gate insulating layer.

It is to be noted that, a gate electrode and the gate line can be formed by adopting the same material through one patterning process. Besides, in the embodiment of the present disclosure, only the necessary film layers are illustrated. The residue of the active layer may built a connection between the data line and the pixel electrode, i.e., the residue of the active layer lap with the data line and the pixel electrode. Besides, The residue of the active layer may also built a connection between the data line and a common electrode, or other first conductive layer, such as a gate line. The specific positions of the lapping will not be listed herein.

Besides, during the process of forming an array substrate, the preparing sequences of the pixel electrode and source-drain electrodes can be exchanged, the embodiment of the present disclosure are not limited thereto.

To sum up, both of the above mentioned preparing solutions show the main technological processes. In fact, the preparing processes of other film layers can be comprised, and the repeated portions are omitted herein.

### Fourth Embodiment

The present embodiment provides a display device, the display device comprises the array substrate according to any one of the above mentioned embodiments. The display device can be a liquid crystal panel, a cellphone, a tablet computer, a television, a display, a notebook, a digital frame, a navigator or any products or components having a display function. According to the understanding of one ordinary skilled person in the art, the other necessary components are comprised in the display device, the repeated portions are omitted herein, the present disclosure is not limited thereto.

The foregoing are merely specific embodiments of the present disclosure, but not limitative to the protection scope of the present disclosure. The alternations or replacements readily envisaged by any skilled person in the art shall be within the protection scope of the present disclosure. Thus, the protection scope of the disclosure should be defined by the accompanying claims.

The present disclosure claims the priority of Chinese patent application No. 201610006819.8, which was filed on Jan. 4, 2016 and is incorporated in its entirety herein by reference as a part of present application.

1. An array substrate, comprising:
a gate insulating layer;
an active layer;
source-drain electrodes, being in contact with the active layer;
a first conductive layer; and
an isolation insulating layer,
wherein the gate insulating layer is located on a surface of the active layer, the isolation insulating layer is located on another surface of the active layer, and the isolation insulating layer at least comprises a first hollow structure in a contacting region of the active layer with the source-drain electrodes; the isolation insulating layer is configured to isolate residue of the active layer located outside a region, where the first hollow structure is located, from contacting the first conductive layer.

2. The array substrate according to claim 1, wherein the first conductive layer and the source-drain electrodes are disposed in a same layer.

3. The array substrate according to claim 1, wherein the isolation insulating layer comprises a second hollow structure in a region where a pixel electrode is located.

4. The array substrate according to claim 1, wherein the first conductive layer comprises any one selected from a group consisting of a data line, a pixel electrode, a gate line and a common electrode.

5. The array substrate according to claim 1, wherein the array substrate is an array substrate with a bottom gate structure, the gate insulating layer is located on a gate line and covers the array substrate, the active layer is located on the gate insulating layer, the isolation insulating layer is located on the active layer, the isolation insulating layer exposes the active layer in the contacting region of the active layer with the source-drain electrodes through the first hollow structure, and the source-drain electrodes are located on the isolation insulating layer and contact an exposed portion of the active layer.

6. The array substrate according to claim 1, wherein the array substrate is an array substrate with a bottom gate structure, the gate insulating layer is located on a gate line and covers the array substrate, the active layer is located on the gate insulating layer, the isolation insulating layer is flush with the active layer, the isolation insulating layer exposes the active layer in the contacting region of the active layer with the source-drain electrode through the first hollow structure, and the source-drain electrodes are located on the isolation insulating layer and contact an exposed portion of the active layer.

7. The array substrate according to claim 1, wherein the array substrate is an array substrate with a top gate structure, the isolation insulating layer is located on the source-drain electrodes, the isolation insulating layer exposes the source-drain electrodes in the contacting region of the active layer with the source-drain electrodes through the first hollow structure, the active layer is located on the isolation insulating layer and contacts an exposed portion of the source-drain electrodes, the gate insulating layer is located on the active layer and covers the array substrate, and a gate line is located on the gate insulating layer.

8. The array substrate according to claim 5, further comprising:
a gate electrode, wherein the gate electrode and the gate line are disposed in a same layer.

9. The array substrate according to claim 5, wherein a thickness of the isolation insulating layer is larger than or equal to a thickness of the active layer.

10. The array substrate according to claim 1, wherein a material of the isolation insulating layer comprises resin.

11. The array substrate according to claim 10, wherein the material of the isolation insulating layer comprises photosensitive resin.

12. A manufacturing method of an array substrate, comprising:
forming a gate insulating layer;
forming an active layer with a first pattern;
forming source-drain electrodes with a second pattern and a first conductive layer with a third pattern, the source-drain electrodes being in contact with the active layer; and
forming an isolating insulating layer with a fourth pattern,
wherein the gate insulating layer is located on a surface of the active layer, the isolation insulating layer is located on another surface of the active layer, and the isolating insulating layer at least comprises a first hollow structure in a contacting region of the active layer with the source-drain electrodes; the isolation insulating layer is configured to isolate residue of the active layer from contacting any conductive layer.

13. The method according to claim 12, wherein the isolation insulating layer is configured to isolate the residue of the active layer from contacting the first conductive layer.

14. The method according to claim 12, wherein the array substrate is an array substrate with a bottom gate structure, and the manufacturing method of the array substrate further comprises:
forming the gate insulating layer on a gate electrode to cover the array substrate;
forming the active layer with the first pattern on the gate insulating layer;
depositing an insulating material on the active layer, using a patterning process to form an isolation insulating layer with a fifth pattern, wherein the isolation insulating exposes the active layer in the contacting region of the active layer with the source-drain electrodes through the first hollow structure; and
forming the source-drain electrodes with the second pattern on the isolation insulating layer, so as to allow the source-drain electrodes to contact an exposed portion of the active layer.

15. The method according to claim 14, wherein forming the gate insulating layer covering the array substrate on the gate electrode further comprises:
forming a gate electrode on a base substrate.

16. The method according to claim 12, wherein the array substrate is an array substrate with a top gate structure, the method further comprises:
depositing an insulating material on the source-drain electrodes with the second pattern, utilizing a pattern process to form an isolation insulating layer with a fifth pattern, wherein the isolation insulating layer exposes the source-drain electrodes in the contacting region of the active layer with the source-drain electrodes through the first hollow structure;
forming the active layer with the first pattern on the isolation insulating layer, so as to allow the active layer to contact an exposed portion of the source-drain electrodes;
forming the gate insulating layer covering the array substrate on the active layer; and
forming a gate line on the gate insulating layer.

17. A display device, comprising the array substrate according to claim 1.

18. The array substrate according to claim 5, wherein the isolation insulating layer comprises a second hollow structure in a region where a pixel electrode is located.

19. The array substrate according to claim 6, wherein the isolation insulating layer comprises a second hollow structure in a region where a pixel electrode is located.

20. The array substrate according to claim 7, wherein the isolation insulating layer comprises a second hollow structure in a region where a pixel electrode is located.
